(19) United States
(12) Patent Application Publication
(10) Pub. No.: US 2022/0044876 A1
(43) Pub. Date: Feb. 10, 2022

(54) CONNECTING MEMBER FOR AN INVERTER AND INVERTER INCLUDING SAID CONNECTING MEMBER

(71) Applicant: ELDOR CORPORATION S.P.A., Orsenigo (Como) (IT)

(72) Inventors: Pasquale FORTE, Castiglione d'Orcia (Siena) (IT); Alessandro POLI, Milano (IT); Fabio MARIGLIANO, Grandate (Como) (IT)

(21) Appl. No.: 17/416,072

(22) PCT Filed: Dec. 18, 2019
(86) PCT No.: PCT/IB2019/060994

§ 371 Date: Jun. 18, 2021

(30) Foreign Application Priority Data
Dec. 20, 2018 (IT) 102018000020599

(51) Int. Cl. H01G 4/40; H01G 2/04; H02K 11/33

(52) U.S. Cl. CPC H01G 4/40; H02K 11/33; H01G 2/04

(57) ABSTRACT

A connecting member for an inverter includes a support made of electrically insulating material, a first and a second conductive tracks anchored to said support. The support further includes one or more housings designed to contain a plurality of capacitors, provided with an opening for connection with said first and second conductive track.

The present invention relates to a connecting member for an inverter and an inverter including said member.

In greater detail, the present invention mainly applies to the field of rotating electric machines, in particular asynchronous electric motors, which are preferentially employed in traction or automotive applications.

With the increasing development of hybrid/electric vehicles, the growing demand for performances, together with the dimensional constraints imposed, make the design of the layout of machines more and more complex.

One of the problems that the designers face in this regard is the reduction of losses and the increase in electrical efficiency within the driving electronics.

For example, the connection existing between power electronics (power module) and the capacitors inside the inverter often results in significant electrical losses, mainly due to the need to position such components remotely and in locations that are not always adjacent.

The object of the present invention is therefore to provide a connecting member for an inverter and an inverter with increased efficiency and reduced overall dimensions.

Said objects are achieved by a connecting member for an inverter having the features of one or more of the following claims 1 to 7, as well as by an inverter having the features of one or more of claims 8 to 9.

In particular, the connecting member comprises a support made of electrically insulating material and a plurality of conducting members.

Preferably, a first and a second conductive tracks anchored to said support and extending between at least one first and one second end are provided.

Preferably, the first and second tracks are arranged close to each other and co-moulded with said support made of electrically insulating material.

In addition, preferably, the support comprises one or more housings designed to contain a plurality of capacitors, provided with an opening for connection with said first and second conductive tracks.

Advantageously, the capacitors and the power modules are thereby in close position and connected to the same tracks, to the benefit of the electrical efficiency of the inverter.

Preferably, the first and second conductive tracks are overlapped on each other and at least partially embedded within said support.

More preferably, the first and second conductive tracks are co-moulded with said support.

Structurally, preferably, the support comprises a substantially flat wall to which said first and second conductive tracks are anchored, preferably at least partially embedded, and extending in a main plane which, in use, is orthogonal to a rotation axis of an electric machine to which the inverter is associated.

Said housings extend orthogonally to the main plane and have at least one light connected to both said tracks, in order to allow a direct connection of the respective capacitor to the tracks.

Advantageously, this way, a single connecting member comprises all the components, preferably co-moulded, required for connecting the inverter to the capacitors.

In the preferred embodiment, the substantially flat wall has, in said main plane, a “U” shape so as to arrange itself around said rotation axis of the electric machine.

Preferably, the first and second conductive tracks extend along said substantially flat wall and have a “U” shape.

The connecting member described hitherto is preferably inserted into an inverter for an electric machine.

The inverter comprises a casing provided with at least one flat support, a plurality of power modules anchored to said flat support and a plurality of capacitors.

The connecting member is connected to said flat support.

Preferably, the first and second conductive tracks have a plurality of second ends electrically connected to each of said power modules.

More preferably, the capacitors are housed in said one or more housings and electrically connected along said first and said second conductive tracks.

In addition, preferably, the power modules are arranged sequentially one after another in a plane orthogonal to said rotation axis and according to a “U” configuration. The connecting member is arranged radially inside the power modules, around said rotation shaft.

These and other features with the related advantages will become more apparent from the following exemplary, therefore non-limiting, description of a preferred, therefore not exclusive, embodiment of a connecting member for an inverter and an inverter as illustrated in the attached figures, wherein:

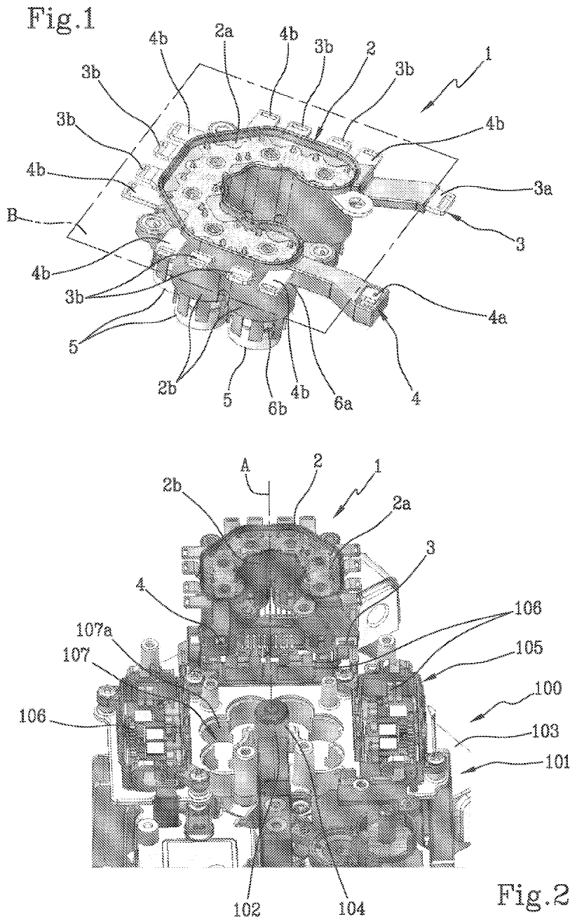

FIG. 1 shows a connecting member according to the present invention;

FIG. 2 shows the connecting member in FIG. 1 being assembled on the inverter;

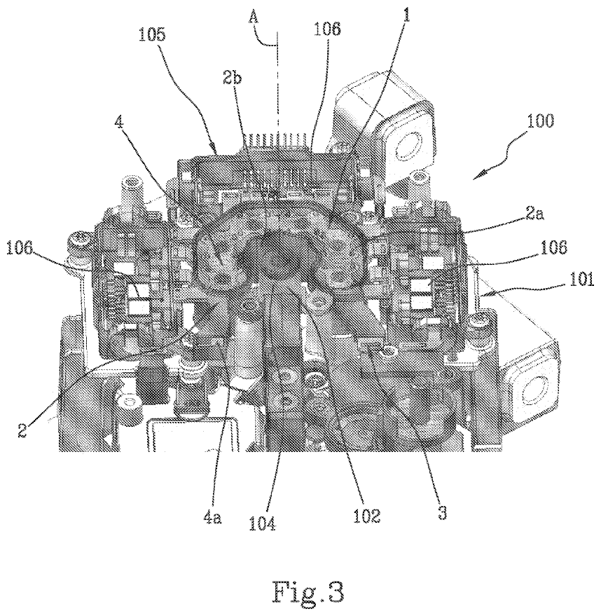

FIG. 3 shows an electric machine on which the inverter in FIG. 2 is fitted.

With reference to the appended figures, number 1 indicates a connecting member for an inverter 105 according to the present invention, preferably used within an electric machine 100.

Such connecting member 1 is configured to electrically connect the power modules 106 to the capacitors 5 of the inverter 105.

In the preferred embodiment, such inverter 105 is inserted into an electric machine 100 of the asynchronous type, more preferably of the wound rotor type.

With reference to FIG. 3, this electric machine 100 therefore comprises a stator 101, provided with a frame 103 and a multi-phase winding (not shown), and a rotor 102, provided with a rotation shaft 104 extending along a rotation axis “A”.

The inverter 105 is electrically connected to the winding of the stator 101 and constrained to said frame 103.

In particular, the inverter 105 comprises a casing (not illustrated as a whole) equipped with a flat support 107 for interfacing with the frame 103 of the stator 101.

Inside the casing, preferably on the flat support 107, a plurality of power modules 106 and the connecting member 1 are positioned.

The power modules 106 are each associated with a phase of said winding; in the illustrated embodiment, the electric machine 100 has a three-phase winding, and therefore three power modules 106 are illustrated.

Preferably, the power modules 106 are arranged sequentially one after another in a plane orthogonal to said rotation axis “A” and according to a “U”, i.e. Horseshoe, configuration;

More preferably, the power modules 106 are arranged in a radially external (i.e. peripheral) portion of the flat support 107.

At the centre of such support 107 there is a central cavity 108 to be crossed by the rotation shaft 104 perimetrically delimited by an edge.

The connecting member 1 according to the present invention is preferably inserted into the inverter 105 described hitherto.

Such connecting member comprises a support 2 made of electrically insulating (or dielectric) material shaped to be housed at the inverter 105 and, preferably, provided with anchoring portions with the flat support 107 of the inverter 105.

Electrically insulating material herein is meant to define, for example, Poliparaphenylene sulfide (PPS), alternatively Polybutylene Terephthalate (PBT).

The electrical connecting members are anchored to the support 2.

In particular, the connecting member 1 comprises a first conductive track 3 anchored to said support 2 and extending between at least one first 3a and one second end 3.

Likewise, a second conductive track 4 anchored to said support 2 and extending between at least one first 4a and one second end 4b is provided.

In use, the first end 3a of the first track 3 is preferably connected at the “engine” side, in particular to an excitation module.

The first end 4a of the second track 4 is preferably connected at the power supply side, in particular to an EMI filter or other element.

By contrast, the second ends 3b, 4b of the first and second tracks are connected to the power modules 106.

Preferably, in this respect, both the first 3 and the second 4 conductive tracks have a plurality of second ends 3b, 4b mutually distributed (in pairs) along the extension of the respective track 3, 4, each being connectable to the power module associated with a respective phase of a stator winding of the electric machine 100.

In the illustrated embodiment, the machine is of the three-phase type and therefore the tracks 3, 4 each have three pairs of second ends 3b, 4b, preferably placed at a substantially constant pitch.

According to an aspect of the invention, the first 3 and said second 4 conductive tracks are overlapped on each other and at least partially embedded within said support 2.

Structurally, the support 2 preferably has a substantially flat wall 2a to which the conductive tracks 3, 4 are anchored.

This substantially flat wall 2a develops in a main plane “B” which, in use, is orthogonal to a rotation axis “A” of the electric machine 100.

The conductive tracks 3, 4 are preferably anchored (at least partly embedded) in correspondence of the substantially flat wall 2a.

More preferably, at least one of the first 3 and the second 4 conductive tracks is completely embedded within said substantially flat wall 2b.

In the illustrated embodiment, the first conductive track 3 is embedded within the substantially flat wall 2a and the second conductive track is only partially embedded, thus standing outwardly from it.

Preferably, therefore, the conductive tracks and the support are co-moulded.

In addition, preferably, the support comprises a plurality of housings 2b extending from said substantially flat wall 2b, orthogonally thereto, and designed to contain a corresponding plurality of capacitors 5.

That is, the housings extend from the substantially flat wall 2b orthogonally to the main plane “B” (i.e. parallel to the rotation axis “A”).

Preferably, such housings 2b are connected to each of the conductive tracks 3, 4 in order to allow a direct electrical coupling of the respective capacitor 5 to both tracks.

Advantageously, the coupling of the capacitors 5 with the power modules 106 is thereby substantially direct, with minimization of the distance and maximization of the electrical performances.

It should be noted that the substantially flat wall 2a has predetermined transverse overall dimensions, considered in the main plane “B”.

That is, the substantially flat wall 2a covers a predetermined area in the main plane “B”

The housings 2b in turn have transverse overall dimensions contained within said predetermined transverse overall dimensions of the substantially flat wall 2a.

That is, the transverse overall dimensions of the housings do not exceed that of the substantially flat wall and take place mainly in an “axial” extension, i.e. parallel to the rotation axis “A”.

Preferably, it should be noted that each housing 2b has a tubular shape extending orthogonally to said main plane “B” between a first end 6a and a second end 6b.

The first end 6a is secured to the substantially flat wall 2a, provided with at least one opening facing said first 3 and said second 4 conductive tracks.

The second end 6b is distal from said substantially flat wall 2b and is preferably open to allow the respective capacitor to be inserted.

Advantageously, the compactness of the connecting member 1 allows a direct coupling of the same with the capacitors.

Preferably, in fact, the capacitors 5 are each axially engaged in a respective housing 2b and electrically connected to both conductive tracks 3, 4.

In the preferred embodiment, the capacitors 5 are welded to the conductive tracks 3, 4. However, other connection methods could be equivalently used.

It should be noted that, preferably, the capacitor 5 has axial overall dimensions exceeding, in moving away from the substantially flat wall 2a, that of the respective housing 2b.

Advantageously, this simplifies the fitting of the connector into the respective housing 2b.

In this respect, in the preferred embodiment, the second ends 6b of the housings comprise axial (elastic) retaining means for the respective capacitor 5.

Preferably, the substantially flat wall 2a has, in said main plane “B”, a “U” (or horseshoe) shape so as to arrange itself around the rotation axis “A” of the electric machine 100.

In this respect, the first 3 and second 4 conductive tracks also extend along the substantially flat wall 2a and have a “U” shape.

Preferably, also the housings 2b of the capacitors extend away from the flat wall (from the face opposite to that the second conductive track 4 stands from) parallel to each other.

In particular, the housings 2b are arranged side by side and also arranged according to a “U” shape, thus following the profile of the substantially flat wall 2a.

The housings arranged side by side thus define, in correspondence thereof, a side edge of the corrugated connecting member 1.

The connecting member 1 is therefore arranged radially inside the power modules 106 of the inverter 105, around said rotation shaft “A”.

In addition, preferably, the connecting member 1 has an axial extension which does not exceed that of the power modules 106 (i.e. corresponds to them), further bringing the power modules closer to the capacitors.

In addition, preferably, the edge 108a of the central cavity 108 of the flat support 107 has a lobed conformation (i.e. lobed edge) counter-shaped to the side profile of the housings 2b of the connecting member 1.

Advantageously, the connecting member can be thereby fitted in the flat support 107 with a simple axial pressure, like a plug.

The invention achieves the objects and offers important advantages.

In fact, the presence of a compact connecting member that incorporates both the tracks and the capacitors in a reduced volume considerably reduces the losses and increases the electrical efficiency of the inverter.

Moreover, its horseshoe shape allows to apply it centrally to the casing of the inverter, thus making assembly easy and reliable.

1. A connecting member for an inverter, wherein it comprises:
a support made of electrically insulating material;
a first conductive track anchored to said support and extending between at least one first and one second end;
a second conductive track anchored to said support and extending between at least one first and one second end and placed near said first conductive track;
wherein said support comprises one or more housings designed to contain a plurality of capacitors, provided with an opening for connection with said first and second conductive track
and wherein said first and second conductive tracks are co-moulded with said support.

2. The connecting member according to claim 1, wherein said first and said second conductive tracks are overlapped on each other and at least partially embedded within said support.

3. The connecting member according to claim 1, wherein said support comprises a substantially flat wall to which said first and second conductive tracks are anchored and which extends in a main plane which, in use, is orthogonal to a rotation axis of the electric machine.

4. The connecting member according to claim 3, wherein said first and/or said second conductive tracks are embedded within said substantially flat wall.

5. The connecting member according to claim 3, wherein said housings extend from said substantially flat wall, orthogonally to said main plane.

6. The connecting member according to claim 3, wherein each housing has a tubular shape extending orthogonally to said main plane between a first end, having a connection opening facing the first and the second conductive tracks, and a second end, distal from said substantially flat wall.

7. The connecting member according to claim 3, wherein said substantially flat wall has, in said main plane, a “U” shape so as to arrange around a rotation axis of an electric machine; said first and said second conductive tracks extending along said substantially flat wall and having a “U” shape.

8. An inverter comprising:
a casing provided with at least one flat support;
a plurality of power modules anchored to said flat support;
a plurality of capacitors;
a connecting member according to claim 1, engaged with said flat support, wherein:
said first and said second conductive tracks have a plurality of second ends electrically connected to each of said power modules;
said capacitors are housed in said one or more housings and electrically connected along said first and said second conductive tracks.

9. The inverter according to claim 8, wherein:
said power modules are arranged sequentially one after another in a plane orthogonal to said rotation axis and according to a “U” shape;
said connecting member is arranged radially inside the power modules, around said rotation shaft.
